(19) United States
(12) Patent Application Publication
(10) Pub. No.: US 2025/0233082 A1
(43) Pub. Date: Jul. 17, 2025

(54) SEMICONDUCTOR PACKAGE COMPONENT AND METHOD FOR FORMING THE SAME

(71) Applicant: TAIWAN SEMICONDUCTOR MANUFACTURING COMPANY LTD., HSINCHU (TW)

(72) Inventors: LIANG-SHIUAN PENG, TAIPEI CITY (TW); CHIH-HUNG LU, HSINCHU COUNTY (TW)

(21) Appl. No.: 18/411,041

(22) Filed: Jan. 12, 2024

(51) Int. Cl. H01L 23/00; H01L 23/498

(52) U.S. Cl. CPC H01L 23/562; H01L 23/49816; H01L 23/49838; H01L 24/05; H01L 24/29; H01L 2224/05005; H01L 2224/05022; H01L 2224/29026; H01L 2224/291; H01L 2924/01029; H01L 2924/15311

(57) ABSTRACT

A semiconductor package component includes a first conductive line and a second conductive line, a first dielectric layer over the first and second conductive lines, and a second dielectric layer. The first conductive line and the second conductive line are separated from each other by a distance. Each of the first and second conductive lines respectively have a tensile stress. The first dielectric layer has a compressive stress. The second dielectric layer is between the first conductive line and the first dielectric layer, and between the second conductive line and the first dielectric layer. The second dielectric layer has a tensile stress. A thickness of the second dielectric layer is in direct proportion to a ratio of a height of the first conductive line over the distance between the first and second conductive lines.

### BACKGROUND

During formation of an integrated circuit, a semiconductor chip/die including integrated circuit devices may be formed over a surface of a semiconductor substrate in a wafer. The die may include an interconnect structure formed over the integrated circuit devices. A redistribution layer may be formed over the semiconductor substrate, and conductors may be formed over the redistribution layer for providing external electrical connections.

As semiconductor technology evolves, semiconductor chips/dies are becoming smaller. In the meantime, more functions need to be integrated into the semiconductor die. Accordingly, the semiconductor die needs to have ever-greater numbers of I/O pads packed into smaller areas, and densities of the I/O pads are rising quickly. As a result, the packaging of the semiconductor dies becomes more difficult, which adversely affects packaging yield.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 is a flowchart representing a method for forming a semiconductor package component in accordance with aspects of the present disclosure.

FIGS. 2A to 2H are schematic drawings of a semiconductor package component at various fabrication stages constructed in accordance with aspects of one or more embodiments of the present disclosure.

FIGS. 3A to 3F are schematic drawings of a semiconductor package component at various fabrication stages constructed in accordance with aspects of one or more embodiments of the present disclosure.

FIGS. 4A to 4C are schematic drawings of a semiconductor package component at various fabrication stages constructed in accordance with aspects of one or more embodiments of the present disclosure.

FIG. 5 is a schematic drawing of a semiconductor package component in accordance with aspects of one or more embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

This description of illustrative embodiments is intended to be read in connection with the accompanying drawings, which are to be considered part of the entire written description. In the description of embodiments disclosed herein, any references to direction or orientation are merely intended for convenience of description and are not intended in any way to limit the scope of the present disclosure. Relative terms such as “lower,” “upper,” “horizontal,” “vertical,” “above,” “below,” “up,” “down,” “top” and “bottom” as well as derivatives thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation. Terms such as “attached,” “affixed,” “connected” and “interconnected” refer to a relationship wherein structures are secured or attached to one another either directly or indirectly through intervening structures, as well as both movable or rigid attachments or relationships, unless expressly described otherwise. Moreover, the features and benefits of the disclosure are illustrated by references to the embodiments. Accordingly, the disclosure expressly should not be limited to such embodiments illustrating some possible non-limiting combination of features that may exist alone or in other combinations of features, the scope of the disclosure being defined by the claims appended hereto.

Notwithstanding that the numerical ranges and parameters setting forth the broad scope of the disclosure are approximations, the numerical values set forth in the specific examples are reported as precisely as possible. Any numerical value, however, inherently contains certain errors necessarily resulting from the standard deviation found in the respective testing measurements. Also, as used herein, the terms “substantially,” “approximately” or “about” generally mean within a value or range that can be contemplated by people having ordinary skill in the art. Alternatively, the terms “substantially,” “approximately” or “about” mean within an acceptable standard error of the mean when considered by one of ordinary skill in the art. People having ordinary skill in the art can understand that the acceptable standard error may vary according to different technologies. Other than in the operating/working examples, or unless otherwise expressly specified, all of the numerical ranges, amounts, values and percentages such as those for quantities of materials, durations of time, temperatures, operating conditions, ratios of amounts, and the likes thereof disclosed herein should be understood as modified in all instances by the terms “substantially,” “approximately” or “about.” Accordingly, unless indicated to the contrary, the numerical parameters set forth in the present disclosure and attached claims are approximations that can vary as desired. At the very least, each numerical parameter should be construed in light of the number of reported significant digits and by applying ordinary rounding techniques. Ranges can be expressed herein as being from one endpoint to another endpoint or between two endpoints. All ranges disclosed herein are inclusive of the endpoints, unless specified otherwise.

A semiconductor package component such as a die or a chip may include a redistribution layer (RDL) electrically connecting external conductors to an interconnect structure of the die. Both the interconnect structure and the RDL include conductive features such as metal lines serving as electrical paths, and dielectric layers providing electrical isolation between metal lines. It is found that the metal lines have tensile stresses, while the dielectric layers have compressive stresses. The two opposite stresses may reduce adhesion between the metal lines and the dielectric layers. In some comparative approaches, delamination is found at an interface between the metal lines and the dielectric layers. In some comparative approaches, a gap-filling capability is reduced due to the stresses, and a dielectric gap-filling issue may arise at a bottom corner of the metal line.

The present disclosure therefore provides a semiconductor package component that including a dielectric layer providing a tensile stress between the tensile-stressed conductive lines and the compressive-stressed dielectric layers. The dielectric layer that provides the tensile stress serves as a buffer layer between the two opposite stresses; therefore, the delamination issue is reduced, and the gap-filling capability is improved.

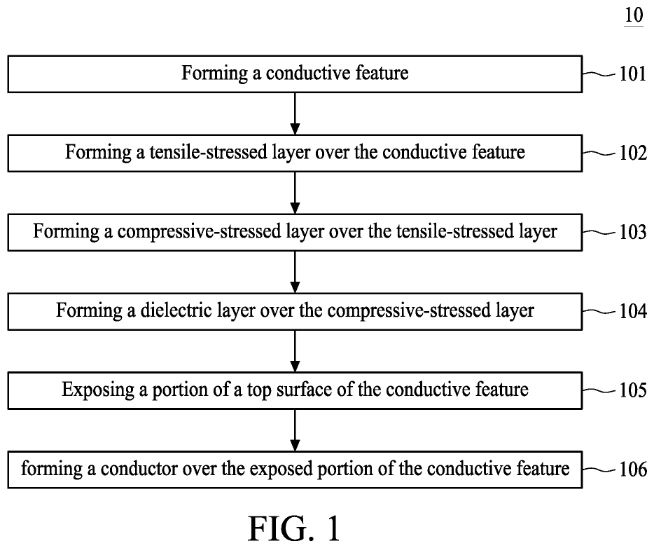

FIG. 1 is a flowchart representing a method for forming a semiconductor package component 10 in accordance with aspects of the present disclosure. The method 10 includes a number of operations (101, 102, 103, 104, 105 and 106). The method 10 will be further described in accordance with one or more embodiments. It should be noted that the operations of the method 10 may be rearranged or otherwise modified within the scope of the various aspects. It should be further noted that additional processes may be provided before, during, and after the method 10, and that some other processes may just be briefly described herein. Thus, other implementations are possible within the scope of the various aspects described herein. It should be appreciated that although a device wafer and a device die are used as examples, the embodiments of the present disclosure may also be applied to form conductive features in other devices (package components) including, but not limited to, package substrates, interposers, packages, and the like.

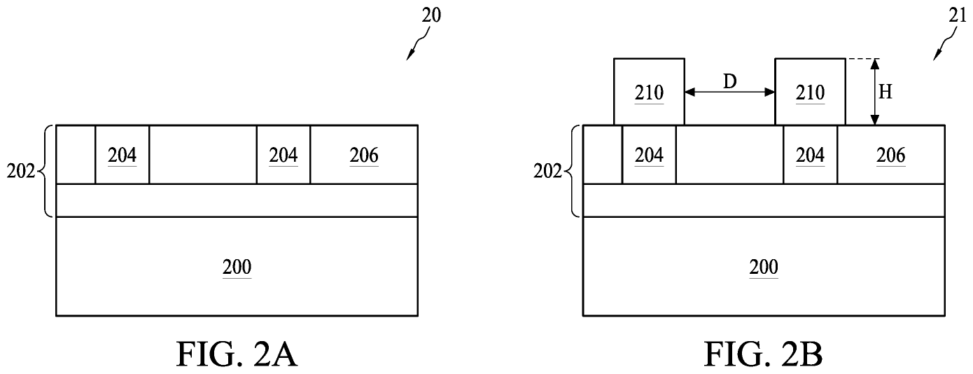

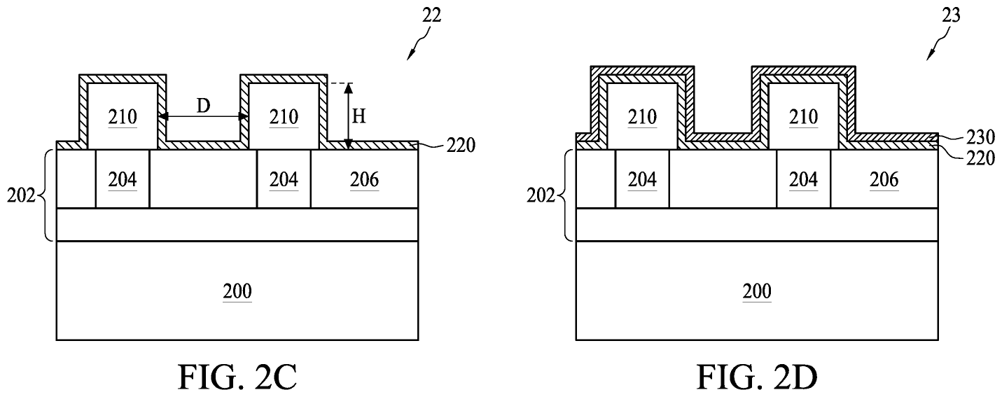

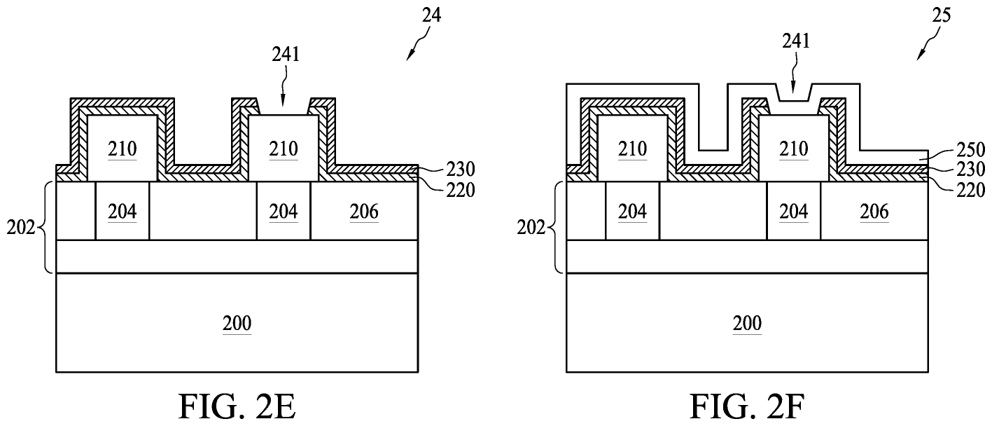

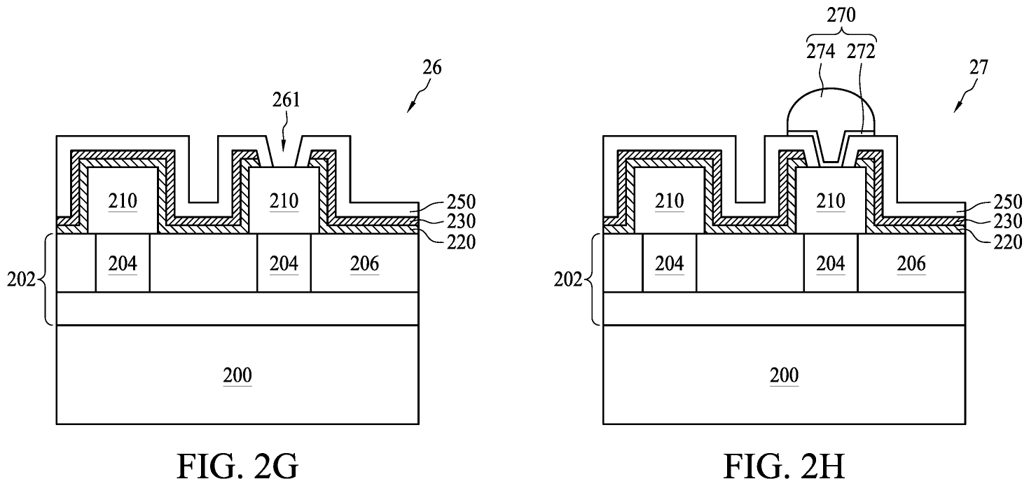

FIGS. 2A to 2H are schematic views of a semiconductor package component at various fabrication stages constructed in accordance with aspects of one or more embodiments of the present disclosure. For example, FIGS. 2A and 2B show an intermediate semiconductor package component 20 and an intermediate semiconductor package component 21, respectively, in accordance with some embodiments corresponding to operation 101. Referring to FIG. 2A, the intermediate semiconductor package component 20 may be a chip formed in a wafer. In some embodiments, the intermediate semiconductor package component 20 may be an interposer wafer, which is free of active devices, and may or may not include passive devices. In other embodiments, the intermediate semiconductor package component 20 may be a package substrate, a package, etc.

Still referring to FIG. 2A, in some embodiments, the intermediate semiconductor package component 20 includes a semiconductor substrate 200. The semiconductor substrate 200 may be mean any construction including semiconductor materials, including, but not limited to, bulk silicon, a semiconductor wafer, a silicon-on-insulator (SOI) substrate, or a silicon germanium substrate. Other semiconductor materials including group III, group IV, and group V elements may also be used. The semiconductor substrate 200 may further include a plurality of isolation features (not shown), such as shallow trench isolation (STI) features or local oxidation of silicon (LOCOS) features. The isolation features may isolate active regions in the semiconductor substrate 200. The intermediate semiconductor package component 20 includes various microelectronic elements. Examples of the various microelectronic elements include transistors (e.g., metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), etc.); resistors; diodes; capacitors; inductors; fuses; and other suitable elements. Various processes are performed to form the various microelectronic elements including deposition, etching, implantation, photolithography, annealing, and other suitable processes. The microelectronic elements are interconnected to form an integrated circuit device, such as a logic device, a memory device (e.g., SRAM), an RF device, an input/output (I/O) device, a system-on-chip (SoC) device, combinations thereof, and other suitable types of devices.

The intermediate semiconductor package component 20 may include inter-layer dielectric (ILD) layers (not shown) and a back-end-of-line (BEOL) interconnect structure 202 electrically connected to the various microelectronic elements. The ILD layers are formed over the semiconductor substrate 200 and fill spaces between the microelectronic elements. In accordance with some embodiments, the ILD layers are formed of phosphosilicate glass (PSG), boro-silicate glass (BSG), boron-doped phosphosilicate glass (BPSG), fluorine-doped silicate glass (FSG), silicon oxide, silicon nitride, silicon oxynitride (SiOxNy), low-k dielectric materials, or the like. The ILD layers may be formed using spin coating, flowable chemical vapor deposition (FCVD), or the like. In accordance with some embodiments, the ILD layers are formed using a deposition method such as plasma-enhanced chemical vapor deposition (PECVD), low-pressure chemical vapor deposition (LPCVD), or the like.

In some embodiments, connecting structures such as contact plugs (not shown) are formed in the ILD layers, and electrically connect the various microelectronic elements to the overlying BEOL interconnect structure 202. In accordance with some embodiments, the contact plugs are formed of or include a conductive material selected from tungsten, aluminum, copper, titanium, tantalum, titanium nitride, tantalum nitride, alloys thereof, and multi-layers thereof. The formation of the contact plugs may include forming contact openings in the ILD layers, depositing conductive material(s) into the contact openings, and performing a planarization process (such as a chemical mechanical polish (CMP) process or a mechanical grinding process) to align or level top surfaces of contact plugs with a top surface of the ILD layers.

The BEOL interconnect structure 202 includes metal lines and vias, which are formed in dielectric layers (also referred to as inter-metal dielectrics (IMDs)). The metal lines at a same level are collectively referred to herein as a metal layer. In accordance with some embodiments, the BEOL interconnect structure 202 includes a plurality of metal layers including the metal lines that are interconnected through the vias. The metal lines and the vias may be formed of copper, copper alloys, or other metals. In accordance with some embodiments, the dielectric layers are formed of low-k dielectric materials. Dielectric constants (k values) of the low-k dielectric materials may be lower than about 3.0, for example. The dielectric layers may include a carbon-containing low-k dielectric material, hydrogen silsesquioxane (HSQ), methylsilsesquioxane (MSQ), or the like. In accordance with some embodiments, the formation of the dielectric layers includes depositing a porogen-containing dielectric material in the dielectric layers and then performing a curing process to drive out the porogen, hereby causing the dielectric layers to be porous.

The formation of the metal lines and the vias in the dielectric layers may include single damascene processes and/or dual damascene processes. Those skilled in the art will realize the formation details of the BEOL interconnect structure 202. The metal lines include top conductive features 204 such as metal lines, metal pads, and vias in a top dielectric layer 206, which is a topmost layer of several dielectric layers. In accordance with some embodiments, the top dielectric layer 206 is formed of a low-k dielectric material similar to a material of lower ones of the dielectric layers. In accordance with other embodiments, the top dielectric layer 206 is formed of a non-low-k dielectric material, which may include silicon nitride, undoped silicate glass (USG), silicon oxide, or the like. In some embodiments, the top dielectric layer 206 may also have a multi-layer structure including, for example, two USG layers and a silicon nitride layer therebetween. The top conductive features 204 may also be formed of copper or a copper alloy, and may have a dual damascene structure or a single damascene structure.

Referring to FIG. 2B, in some embodiments, conductive features 210 are formed over the BEOL interconnect structure 202 according to the operation 101. In some embodiments, the conductive features 210 could be a redistribution layer (RDL) deposited over the top metal layer 204 and the top dielectric layer 206. Suitable materials for the conductive features 210 may include, for example but not limited thereto, copper, aluminum, AlCu, copper alloy, or other conductive materials. As shown in FIG. 2B, the conductive features 210 are electrically connected to the top metal layer 204. Further, the conductive features 210 may also be called a metal pad region (or a metal pad), which is involved in a bonding process to connect the integrated circuits in the intermediate semiconductor package component 21 to external devices or components.

Still referring to FIG. 2B, in some embodiments, the conductive features 210 have a same height H. Further, the conductive features 210 are separated from each other by a distance D. In some embodiments, an aspect ratio of the height H to the distance D is obtained based on two adjacent conductive features 210.

Additionally, each of the conductive features 210 has a tensile stress. In some embodiments, when the conductive features 210 include copper, the conductive feature 210 has a tensile stress between approximately 70 MPa and approximately 90 MPa. In other embodiments, when the conductive features 210 include copper alloy, the conductive feature 210 may have a tensile stress between approximately 200 MPa and approximately 400 MPa, but the disclosure is not limited thereto.

FIG. 2C illustrates an intermediate semiconductor package component 22 in accordance with some embodiments corresponding to operation 102. As shown in FIG. 2C, a dielectric layer 220 is formed over the semiconductor substrate 200 and the conductive features 210. The dielectric layer 220 is conformally formed over the conductive features 210. In some embodiments, the dielectric layer 220 include silicon nitride-based materials. For example but not limited thereto, the dielectric layer 220 may include silicon nitride, silicon oxynitride (SiON), silicon carbon nitride (SiCN), or silicon carbon oxy-nitride (SiCON). The dielectric layer 220 may be formed by chemical vapor deposition (CVD), but the disclosure is not limited thereto. In some embodiments, by adjusting an RF power in the CVD for forming the dielectric layer 220, the dielectric layer 220 may have a tensile stress. Therefore, the dielectric layer 220 is referred to as a tensile-stressed dielectric layer. In some embodiments, the RF power for forming the tensile-stressed dielectric layer 220 is less than approximately 800 W. In some embodiments, the RF power for forming the tensile-stressed dielectric layer 220 is between approximately 400 W and approximately 800 W. In some embodiments, the tensile stress of the tensile-stressed dielectric layer 220 is between approximately 30 MPa and approximately 400 MPa.

Still referring to FIG. 2C, in some embodiments, a thickness of the tensile-stressed dielectric layer 220 is between approximately 200 angstroms and approximately 2,500 angstroms. In some comparative approaches, when the thickness of tensile-stressed dielectric layer 220 is less than 200 angstroms, the tensile stress of the tensile-stressed dielectric layer 220 is not sufficient to cause the tensile-stressed dielectric layer 220 to function as desired. In some comparative approaches, when the thickness of the tensile-stressed dielectric layer 220 is greater than 2,500 angstroms, the tensile stress of the tensile-stressed dielectric layer 220 and the tensile stress of the conductive features 210 may exceed strength limits of entire configuration, and underlying layers may be adversely impacted. Further, when the tensile-stressed dielectric layer 220 has the thickness greater than 2,500 angstroms, a gap-filling issue may arise with layers formed subsequently.

In accordance with some embodiments, the thickness of the tensile-stressed dielectric layer 220 is in direct proportion to the aspect ratio of the height H to the distance D. In some embodiments, the thickness of the tensile-stressed dielectric layer 220 is less than 500 angstroms when the aspect ratio is less than 1. For example but not limited thereto, the thickness of the tensile-stressed dielectric layer 220 is between approximately 200 angstroms and approximately 500 angstroms. In other embodiments, the thickness of the tensile-stressed dielectric layer 220 is between 500 angstroms and 1,000 angstroms when the aspect ratio is between 1 and 2. In still other embodiments, the thickness of the tensile-stressed dielectric layer 220 is greater than 1,000 angstroms when the aspect ratio is greater than 2. For example but not limited thereto, the thickness of the tensile-stressed dielectric layer 220 is between approximately 1,000 angstroms and approximately 2,500 angstroms.

FIG. 2D illustrates an intermediate semiconductor package component 23 in accordance with some embodiments corresponding to operation 103. As shown in FIG. 2D, a dielectric layer 230 is formed over the tensile-stressed dielectric layer 220. The dielectric layer 230 is conformally formed over the conductive features 210 and the tensile-stressed dielectric layer 220. In some embodiments, the dielectric layer 230 may include silicon nitride-based materials. In such embodiments, the tensile-stressed dielectric layer 220 and the dielectric layer 230 may include a same material. In other embodiments, the dielectric layer 230 may include silicon oxide or aluminum nitride, but the disclosure is not limited thereto. In some embodiments, the dielectric layer 230 may be formed by CVD, but the disclosure is not limited thereto. In some embodiments, by adjusting an RF power in the CVD for forming the dielectric layer 230, the dielectric layer 230 may have a compressive stress. Therefore, the dielectric layer 230 is referred to as a compressive-stressed dielectric layer. In some embodiments, the RF power for forming the compressive-stressed dielectric layer 230 is greater than approximately 800 W. In some embodiments, the RF power for forming the compressive-stressed dielectric layer 230 is between approximately 800 W and approximately 1,500 W. In some embodiments, the compressive stress of the compressive-stressed dielectric layer 230 is between approximately 0 MPa and approximately 300 MPa, but the disclosure is not limited thereto. In some embodiments, a thickness of the compressive-stressed dielectric layer 230 may be equal to or greater than the thickness of the tensile-stressed dielectric layer 220. In some embodiments, the thickness of the compressive-stressed dielectric layer 230 is between approximately 2,000 angstroms and approximately 20,000 angstroms, but the disclosure is not limited thereto. In some embodiments, the compressive-stressed dielectric layer 230 may serve as a passivation layer that is used to protect the underlying BEOL interconnect structure 202 and the conductive features 210.

It should be noted that in some comparative approaches without the tensile-stressed dielectric layer 220, the compressive stress of the compressive-stressed dielectric layer 230 may apply directly to the conductive features 210 that have the tensile stresses. Such opposite stresses may cause delamination and cause a gap-filling issue at a bottom corner of the conductive features 210. In contrast to the comparative approaches, the tensile-stressed dielectric layer 220 serves as a buffer layer between the compressive-stressed dielectric layer 230 and the tensile-stressed conductive features 210, such that the compressive stress of the compressive-stressed dielectric layer 230 is not directly applied to the conductive features 210. Accordingly, the abovementioned delamination and gap-filling issue are both mitigated.

Please refer to FIG. 2E, which shows an intermediate semiconductor package component 24 at a stage subsequent to operation 103. In some embodiments, the compressive-stressed dielectric layer 230 and the tensile-stressed dielectric layer 220 are patterned to form at least an opening 241. In some embodiments, the opening 241 may expose a portion of a top surface of the conductive feature 210.

Referring to FIG. 2F, which shows an intermediate semiconductor package component 25 in accordance with some embodiments corresponding to operation 104, a dielectric layer 250 is formed over the compressive-stressed dielectric layer 230. Further, the dielectric layer 250 is conformally formed over the compressive-stressed dielectric layer 230 and formed in the opening 241. In some embodiments, the dielectric layer 250 may be a polymer layer, but the disclosure is not limited thereto. The polymer layer may include a polymer, such as an epoxy, polyimide, benzocyclobutene (BCB), polybenzoxazole (PBO), or the like, although other relatively soft, possibly organic, dielectric materials can also be used. In one embodiment, the polymer layer is a polyimide layer. In another embodiment, the polymer layer is a polybenzoxazole (PBO) layer. The polymer layer is soft, and hence serves a function of reducing inherent stresses imposed on the semiconductor substrate 200. In addition, the polymer layer is easily formed to a thickness of tens of microns.

Please refer to FIG. 2G, which shows an intermediate semiconductor package component 26 at a stage corresponding to operation 105. In some embodiments, the dielectric layer 250 is patterned to form an opening 261. In such embodiments, the opening 261 exposes a portion of the top surface of the conductive feature 210.

Please refer to FIG. 2H, which shows a semiconductor package component 27 in accordance with some embodiments corresponding to operation 106. In some embodiments, a conductor 270 is formed over the exposed portion of the conductive feature 210. In some embodiments, the conductor 270 may include an under-bump-metallurgy (UBM) layer 272 and a conductive layer 274. The UBM layer 272 is formed over a portion of the dielectric layer 250 and over the exposed portion of the top surface of the conductive feature 210. The UBM layer 272 may be a multiple layer. For example but not limited thereto, the UBM layer 272 may include a diffusion barrier layer and a metal seed layer, but the disclosure is not limited thereto. In some embodiments, the diffusion barrier layer may be formed of titanium (Ti), titanium nitride (TiN), tantalum nitride (TaN), tantalum (Ta), or the like. In some embodiments, the metal seed layer may be a copper seed layer. The conductive layer 274 is formed over the UBM layer 272. In some embodiments, the conductive layer 274 includes copper, but the disclosure is not limited thereto. In some embodiments, the conductive layer 274 may be a bump. In other embodiments, the conductive layer 274 may be a copper post. Still referring to FIG. 2H, the conductor 270 is electrically connected to the conductive feature 210. Accordingly, the conductor 270 provides external electrical connection to the semiconductor package component 27.

Accordingly, the semiconductor package component 27 includes the conductive features 210 (which can be conductive lines or conductive pads), the tensile-stressed dielectric layer 220, and the compressive-stressed dielectric layer 230. The conductive features 210 having the tensile stress, the tensile-stressed dielectric layer 220, and the compressive-stressed dielectric layer 230 form a stress scheme with the tensile-stressed dielectric layer 220 serving as a buffer between the tensile-stressed conductive features 210 and the compressive-stressed dielectric layer 230. Accordingly, the opposite stresses from the tensile-stressed conductive features 210 and the compressive-stressed dielectric layer 230 are not in direct contact. Accordingly, the delamination issue between the conductive features 210 and the overlying layers, and the gap-filling issue at the bottom corner of the conductive features 210, are both mitigated.

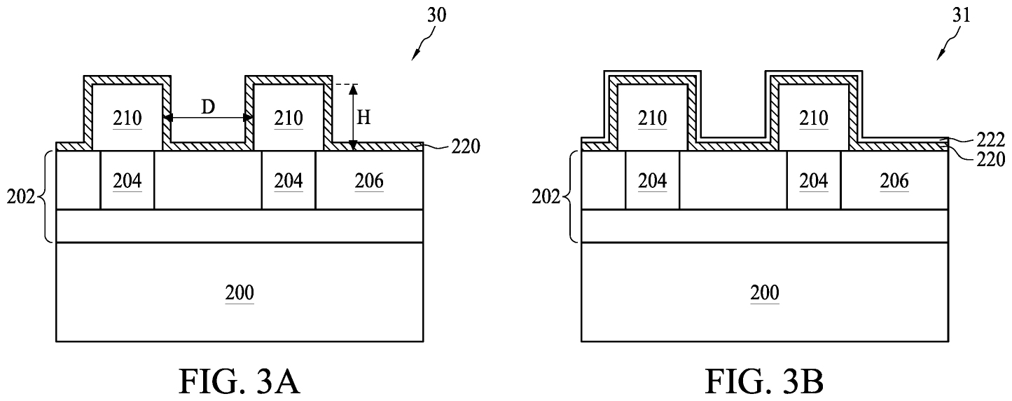

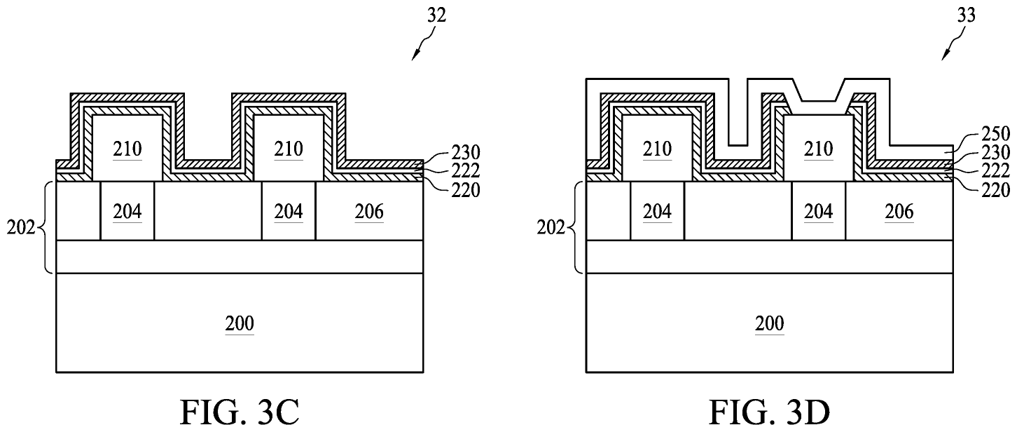

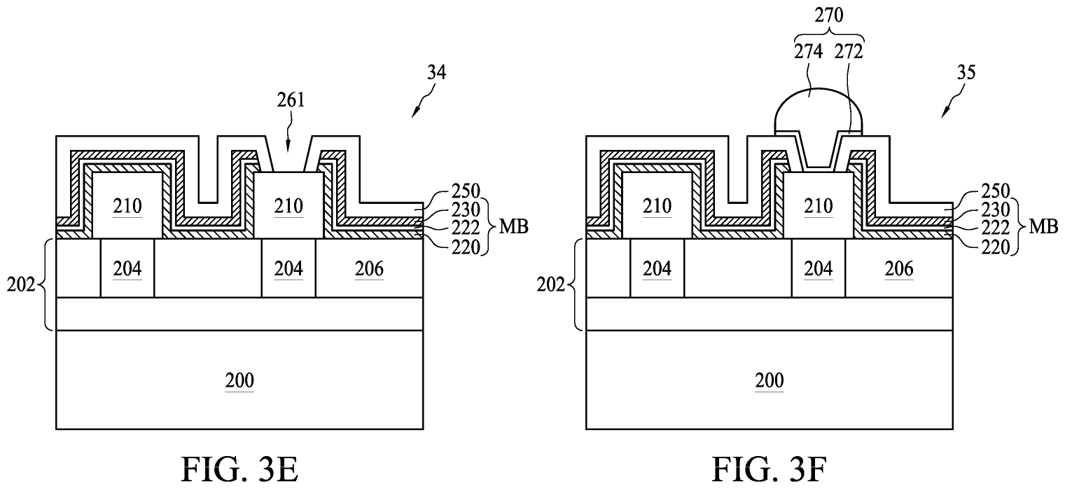

Please refer to FIGS. 3A to 3F, which are schematic views of a semiconductor package component at various fabrication stages constructed in accordance with aspects of one or more embodiments of the present disclosure. It should be noted that same elements in FIGS. 2A to 2H and FIGS. 3A to 3F may include same materials; therefore, repeated descriptions are omitted for brevity. FIG. 3A shows an intermediate semiconductor package component 30 in accordance with some embodiments corresponding to the operations 101 and 102. Referring to FIG. 3A, the intermediate semiconductor package component 30 may be a chip formed in a wafer, an interposer wafer, a package substrate, a package, etc.

The intermediate semiconductor package component 30 includes a semiconductor substrate 200. The semiconductor substrate 200 may further comprise a plurality of isolation features (not shown) for defining and isolating active regions in the semiconductor substrate 200. The intermediate semiconductor package component 30 includes various microelectronic elements, ILD layers filling spaces between the microelectronic elements, and a BEOL interconnect structure 202 for providing electrical connection to the microelectronic elements. As mentioned above, the BEOL interconnect structure 202 includes conductive features such as metal lines and vias, which are formed in IMD layers, though not shown.

Still referring to FIG. 3A, in some embodiments, conductive features 210 are formed over the BEOL interconnect structure 202 according to the operation 101. In some embodiments, the conductive features 210 could be an RDL deposited over top metal lines 204 and a top dielectric layer 206 of the BEOL interconnect structure 202. As shown in FIG. 3A, the conductive features 210 are electrically connected to the top metal lines 204. As mentioned above, the conductive features 210 may also be called a metal pad region (or metal pad), which is involved in a bonding process to connect the integrated circuits in the intermediate semiconductor package component 30 to external devices or components. The conductive features 210 may have a same height H. The conductive features 210 are separated from each other by a distance D. In some embodiments, an aspect ratio of the height H to the distance D is obtained based on two adjacent conductive features 210. Additionally, each of the conductive features 210 has a tensile stress.

Still referring to FIG. 3A, in some embodiments, a tensile-stressed dielectric layer 220 is formed over the semiconductor substrate 200 and the conductive features 210 according to operation 102. As shown in FIG. 3A, the tensile-stressed dielectric layer 220 is conformally formed over the conductive features 210. As mentioned above, the tensile-stressed dielectric layer 220 is formed by CVD. By adjusting an RF power in the CVD, the tensile stress is obtained. As mentioned above, a thickness of the tensile-stressed dielectric layer 220 is in direct proportion to the aspect ratio of the height H to the distance D.

Please refer to FIG. 3B, which shows an intermediate semiconductor package component 31 at a stage subsequent to the operation 102. In some embodiments, a dielectric layer 222 is formed over the tensile-stressed dielectric layer 220. The dielectric layer 222 may include a dielectric material different from that of the tensile-stressed dielectric layer 220. For example, the dielectric layer 222 may include silicon oxide-based dielectric material, while the tensile-stressed dielectric layer 220 may include silicon nitride-based dielectric material. The thickness of the tensile-stressed dielectric layer 220 is greater than a thickness of the dielectric layer 222. In some embodiments, the thickness of the dielectric layer 222 is between approximately 1 angstrom and approximately 5 angstroms, but the disclosure is not limited thereto. In some embodiments, the dielectric layer 222 has a compressive stress. In other embodiments, the dielectric layer 222 may be free of stress.

Referring to FIG. 3C, which shows an intermediate semiconductor package component 32 in accordance with some embodiments corresponding to the operation 103, a compressive-stressed dielectric layer 230 is formed over the dielectric layer 222. As shown in FIG. 3C, the compressive-stressed dielectric layer 230 is conformally formed over the conductive features 210, the tensile-stressed dielectric layer 220 and the dielectric layer 222. As mentioned above, the compressive-stressed dielectric layer 230 may include silicon nitride-based materials. In such embodiments, the tensile-stressed dielectric layer 220 and the compressive-stressed dielectric layer 230 may include a same material. In other embodiments, the compressive-stressed dielectric layer 230 may include silicon oxide or aluminum nitride, but the disclosure is not limited thereto. As mentioned above, the compressive-stressed dielectric layer 230 is formed by CVD, and by adjusting an RF power in the CVD, the compressive stress is obtained. In some embodiments, a thickness of the compressive-stressed dielectric layer 230 may be equal to or greater than the thickness of the tensile-stressed dielectric layer 220. In some embodiments, the compressive-stressed dielectric layer 230 may serve as a passivation layer that is used to protect the underlying BEOL interconnect structure 202 and the conductive features 210.

In some embodiments, the tensile-stressed dielectric layer 220 and the dielectric layer 222 are referred to as a multi-layered buffer structure MB. The dielectric layer 222 that has the compressive stress or is free of stress is disposed between the tensile-stressed dielectric layer 220 and the compressive-stressed dielectric layer 230. In such embodiments, the dielectric layer 222 further buffers the opposite stresses from the compressive-stressed dielectric layer 230 and the tensile-stressed dielectric layer 220.

Please refer to FIG. 3D, which shows an intermediate semiconductor package component 33 in accordance with some embodiments corresponding to the operation 104. In some embodiments, the compressive-stressed dielectric layer 230, the dielectric layer 222 and the tensile-stressed dielectric layer 220 are patterned to form at least an opening (not shown). In some embodiments, the opening may expose a portion of a top surface of the conductive feature 210. Still referring to FIG. 3D, in some embodiments, a dielectric layer 250 is formed over the compressive-stressed dielectric layer 230 according to the operation 104. As mentioned above, the dielectric layer 250 may be a polymer layer, but the disclosure is not limited thereto. The polymer layer is soft, and hence serves a function of reducing inherent stresses imposed on the semiconductor substrate 200. In addition, the polymer layer is easily formed to a thickness of tens of microns.

Please refer to FIG. 3E, which shows an intermediate semiconductor package component 34 at a stage corresponding to the operation 105. In some embodiments, the dielectric layer 250 is patterned to form an opening 261. In such embodiments, the opening 261 exposes the portion of the top surface of the conductive feature 210.

Please refer to FIG. 3F, which shows a semiconductor package component 35 in accordance with some embodiments corresponding to the operation 106. In some embodiments, a conductor 270 is formed over the exposed portion of the conductive feature 210. In some embodiments, the conductor 270 may include a UBM layer 272 and a conductive layer 274. As shown in FIG. 3F, the conductor 270 is electrically connected to the conductive feature 210. Accordingly, the conductor 270 provides external electrical connection to the semiconductor package component 35.

Accordingly, the semiconductor package component 35 includes the conductive features 210 (which can be conductive lines or conductive pads), the multi-layered buffer structure MB, and the compressive-stressed dielectric layer 230. The multi-layered buffer structure MB includes the tensile-stressed dielectric layer 220 and the dielectric layer 222. In some embodiments, a stress scheme is formed by the conductive tensile-stressed conductive features 210, the multi-layered buffer structure MB including the tensile-stressed dielectric layer 220 and the dielectric layer 222, and the compressive-stressed dielectric layer 230. The tensile-stressed dielectric layer 220 serves as a buffer between the tensile-stressed conductive features 210 and the compressive-stressed dielectric layer 230 such that the opposite stresses from the tensile-stressed conductive features 210 and the compressive-stressed dielectric layer 230 are not in direct contact. The dielectric layer 222 (which has the compressive stress or is free of stress) between the tensile-stressed dielectric layer 220 and the compressive-stressed dielectric layer 230 further serves as a buffer layer between the layers 220 and 230. Accordingly, the delamination issue between the conductive features 210 and the overlying layers, and the gap-filling issue at the bottom corner of the conductive features 210, are both mitigated.

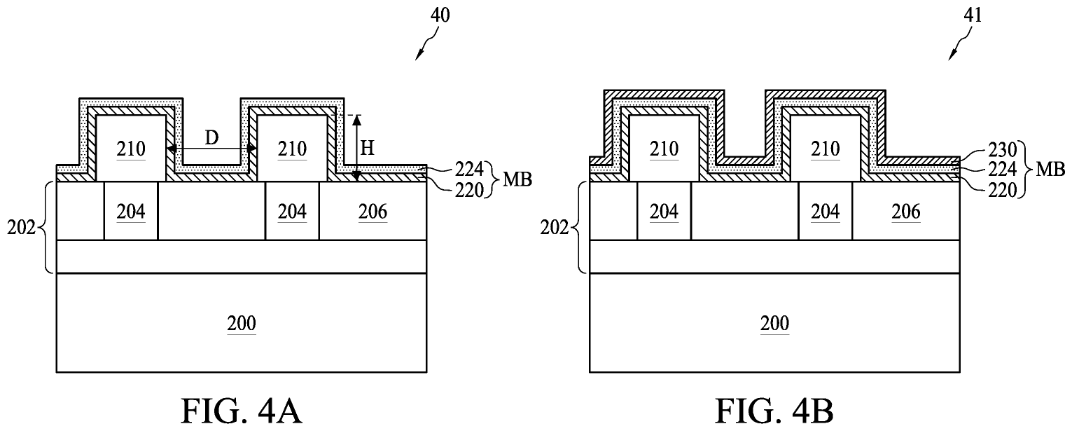

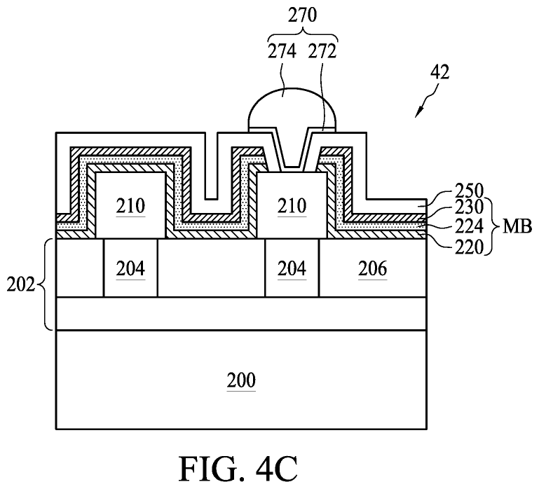

Please refer to FIGS. 4A to 4C, which are schematic views of a semiconductor package component at various fabrication stages constructed in accordance with aspects of one or more embodiments of the present disclosure. It should be noted that same elements in FIGS. 2A to 2H and FIGS. 4A to 4C may include same materials; therefore, repeated descriptions are omitted for brevity. FIG. 4A shows an intermediate semiconductor package component 40 in accordance with some embodiments corresponding to the operations 101 and 102. Referring to FIG. 4A, the intermediate semiconductor package component 40 may be a chip formed in a wafer, an interposer wafer, a package substrate, a package, etc.

As mentioned above, the intermediate semiconductor package component 40 includes a semiconductor substrate 200, various microelectronic elements, ILD layers filling spaces between the microelectronic elements, and a BEOL interconnect structure 202 for providing electrical connection to the microelectronic elements. As mentioned above, the BEOL interconnect structure 202 includes conductive features such as metal lines and vias, which are formed in IMD layers, though not shown.

In some embodiments, conductive features 210 are formed over the BEOL interconnect structure 202 according to the operation 101. The conductive features 210 have a same height H. Further, the conductive features 210 are separated from each other by a distance D. In some embodiments, an aspect ratio of the height H to the distance D is obtained based on two adjacent conductive features. 210. Additionally, each of the conductive features 210 has a tensile stress.

In some embodiments, a tensile-stressed dielectric layer 220 is formed over the semiconductor substrate 200 and the conductive features 210 according to the operation 102. As shown in FIG. 4A, the tensile-stressed dielectric layer 220 is conformally formed over the conductive features 210. As mentioned above, the tensile-stressed dielectric layer 220 is formed by CVD, and by adjusting an RF power in the CVD, the tensile stress is obtained. A thickness of the tensile-stressed dielectric layer 220 is in direct proportion to the aspect ratio of the height H to the distance D.

Still referring to FIG. 4A, in some embodiments, a dielectric layer 224 is formed over the tensile-stressed dielectric layer 220. The dielectric layer 224 may include a dielectric material same as that of the tensile-stressed dielectric layer 220. The thickness of the tensile-stressed dielectric layer 220 is greater than a thickness of the dielectric layer 224. In some embodiments, the dielectric layer 224 may be formed by CVD, and by adjusting an RF power in the CVD, the tensile stress is obtained. Therefore, the dielectric layer 224 may be another tensile-stressed dielectric layer. Further, the tensile stress of the tensile-stressed dielectric layer 224 is less than the tensile stress of the tensile-stressed dielectric layer 220. Therefore, the tensile-stressed dielectric layer 220 and the tensile-stressed dielectric layer 224 are referred to as a multi-layered buffer structure MB having to a gradient tensile stress from a bottom to a top. In other embodiments, the dielectric layer 224 may be formed free of stress due to adjusting of the RF power in the CVD.

In some embodiments, one or more tensile-stressed dielectric layers (not shown) may be formed over the tensile-stressed dielectric layer 224, and a tensile stress of such tensile-stressed dielectric layers is less than the tensile stress of the tensile-stressed dielectric layer 224. In some embodiments, the one or more tensile-stressed dielectric layers, the tensile-stressed dielectric layer 224, and the tensile-stressed dielectric layer 220 form a multi-layered buffer structure MB that has a gradient tensile stress from a bottom to a top. It should be noted that although two tensile-stressed dielectric layers 220 and 224 are shown, a number of the tensile-stressed dielectric layers can be adjusted according to various product designs.

Referring to FIG. 4B, which shows an intermediate semiconductor package component 41 in accordance with some embodiments corresponding to the operation 103, a compressive-stressed dielectric layer 230 is formed over the tensile-stressed dielectric layer 224. As shown in FIG. 4B, the compressive-stressed dielectric layer 230 is conformally formed over the conductive features 210, the tensile-stressed dielectric layer 220, and the tensile-stressed dielectric layer 224. As mentioned above, the compressive-stressed dielectric layer 230 may include silicon nitride-based materials. In such embodiments, the tensile-stressed dielectric layer 220, the tensile-stressed dielectric layer 224, and the compressive-stressed dielectric layer 230 may include a same material. As mentioned above, the compressive-stressed dielectric layer 230 is formed by CVD, and by adjusting an RF power in the CVD, the compressive stress is obtained.

In some embodiments, the tensile-stressed dielectric layer 220 and the tensile-stressed dielectric layer 224 form the multi-layered buffer structure MB having a stress gradient. The stress gradient helps to provide a more effective buffer between the opposite stresses from the compressive-stressed dielectric layer 230 and the tensile-stressed conductive features 210.

Please refer to FIG. 4C, which shows a semiconductor package component 42 in accordance with some embodiments corresponding to the operations 104 to 106. In some embodiments, the compressive-stressed dielectric layer 230, the tensile-stressed dielectric layer 224 and the tensile-stressed dielectric layer 220 are patterned to form at least an opening (not shown). A dielectric layer 250 is formed over the compressive-stressed dielectric layer 230 according to the operation 104. As mentioned above, the dielectric layer 250 may be a polymer layer, but the disclosure is not limited thereto.

The dielectric layer 250 is patterned to form an opening that exposes a portion of a top surface of the conductive feature 210 according to the operation 105. A conductor 270 is formed over the exposed portion of the conductive feature 210 according to the operation 106. In some embodiments, the conductor 270 may include a UBM layer 272 and a conductive layer 274. The conductor 270 provides external electrical connection to the semiconductor package component 42.

Accordingly, the semiconductor package component 42 includes the conductive features 210 (which can be conductive lines or conductive pads), the multi-layered buffer structure MB, and the compressive-stressed dielectric layer 230. The multi-layered buffer structure MB includes the tensile-stressed dielectric layer 220 and the tensile-stressed dielectric layer 224. In some embodiments, a stress scheme is formed by the tensile-stressed conductive features 210, the multi-layered buffer structure MB including the tensile-stressed dielectric layer 220 and the tensile-stressed dielectric layer 224, and the compressive-stressed dielectric layer 230. The multi-layered buffer structure MB between the tensile-stressed conductive features 210 and the compressive-stressed dielectric layer 230 serves as a buffer such that the opposite stresses from the tensile-stressed conductive features 210 and the compressive-stressed dielectric layer 230 are not in direct contact. Further, the multi-layered buffer structure MB may have a stress gradient that further helps to provide an effective buffer function. Accordingly, the delamination issue between the conductive features 210 and the overlying layers, and the gap-filling issue at the bottom corner of the conductive features 210, are both mitigated.

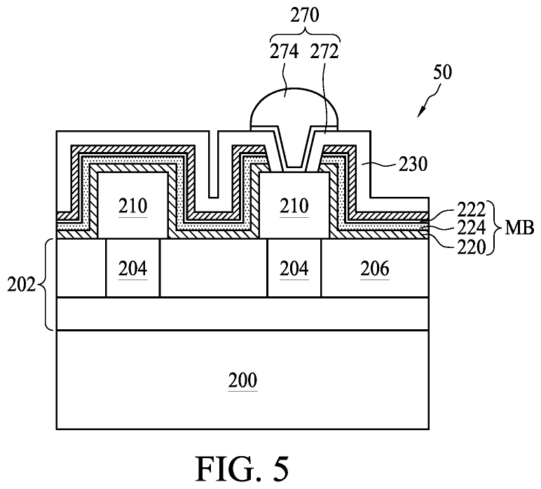

Please refer to FIG. 5, which is a schematic view showing a semiconductor package component in accordance with aspects of one or more embodiments of the present disclosure. In some embodiments, the semiconductor package component 50 can be formed by the method 10. The semiconductor package component 50 includes conductive features 210 (which can be conductive lines or conductive pads), a multi-layered buffer structure MB, and a compressive-stressed dielectric layer 230. The multi-layered buffer structure MB may include a tensile-stressed dielectric layer 220, a tensile-stressed dielectric layer 224, and a compressive-stressed dielectric layer 222. In some embodiments, the multi-layered buffer structure MB is disposed between the conductive features 210 and the compressive-stressed dielectric layer 230. The compressive-stressed dielectric layer 222 of the multi-layered buffer structure MB is disposed between the compressive-stressed dielectric layer 230 and the tensile-stressed dielectric layers 220 and 224, while the tensile-stressed dielectric layer 224 is disposed between the compressive-stressed dielectric layer 222 and the tensile-stressed dielectric layer 220. In some embodiments, the conductive tensile-stressed conductive features 210, the multi-layered buffer structure MB (including the tensile-stressed dielectric layer 220, the tensile-stressed dielectric layer 224 and the compressive-stressed dielectric layer 222), and the compressive-stressed dielectric layer 230 form a stress scheme. The multi-layered buffer structure MB between the tensile-stressed conductive features 210 and the compressive-stressed dielectric layer 230 serves as a buffer such that the opposite stresses from the tensile-stressed conductive features 210 and the compressive-stressed dielectric layer 230 are not in direct contact. The multi-layered buffer structure MB may have a stress gradient that further helps to provide an effective buffer function. The multi-layered buffer structure MB may have the compressive-stressed dielectric layer 222 between the compressive-stressed dielectric layer 230 and the tensile-stressed dielectric layers 220 and 224 to serve as a buffer between the opposite stresses. Accordingly, the delamination issue between the conductive features 210 and the overlying layers, and the gap-filling issue at the bottom corner of the conductive features 210, are both mitigated.

In some embodiments, the stress scheme may include a conductive feature such as a metal layer formed in a BEOL interconnect structure, a tensile-stressed dielectric layer over the metal layer, and a compressive-stressed dielectric layer over the tensile-stressed dielectric layer. In some embodiments, an overlying metal layer may be formed in the compressive-stressed dielectric layer and may be electrically connected to the metal layer. In such embodiments, the tensile-stressed dielectric layer helps to buffer the tensile stress from the metal layer and the compressive stress from the compressive-stressed dielectric layer. Therefore, a delamination issue may be mitigated. In some embodiments, the stress scheme may include a multi-layered buffer structure, and the multi-layered buffer structure may include the abovementioned tensile-stressed dielectric layers and the abovementioned compressive-stressed dielectric layer; therefore, such details are omitted for brevity.

Accordingly, the present disclosure provides a semiconductor package component that includes a dielectric layer having a tensile stress between tensile-stressed conductive lines and compressive-stressed dielectric layers. The dielectric layer, which has the tensile stress serves, serves as a buffer layer between the two opposite stresses; therefore, a delamination issue is reduced, and a gap-filling capability is improved.

In accordance with some embodiments of the present disclosure, a semiconductor package component is provided. The semiconductor package component includes a first conductive line and a second conductive line, a first dielectric layer over the first and second conductive lines, and a second dielectric layer. The first conductive line and the second conductive line are separated from each other by a distance. Each of the first and second conductive lines has a tensile stress. The first dielectric layer has a compressive stress. The second dielectric layer is between the first conductive line and the first dielectric layer, and between the second conductive line and the first dielectric layer. The second dielectric layer has a tensile stress. A thickness of the second dielectric layer is in direct proportion to a ratio of a height of the first conductive line to the distance between the first and second conductive lines.

In accordance with some embodiments of the present disclosure, a semiconductor package component is provided. The semiconductor package component includes a conductive feature, a dielectric layer over the conductive feature, and a multi-layered buffer structure between the conductive feature and the dielectric layer. The conductive feature has a tensile stress, the dielectric layer has a compressive stress, and the multi-layered buffer structure has a tensile stress. A thickness of the multi-layered buffer structure is equal to or less than a thickness of the dielectric layer.

In accordance with some embodiments of the present disclosure, a method for forming a semiconductor package component is provided. The method includes following operations. A conductive feature is formed. A tensile-stressed layer is formed over the conductive feature. A compressive-stressed layer is formed over the tensile-stressed layer. A dielectric layer is formed over the compressive-stressed layer. A portion of a top surface of the conductive feature is exposed. A conductor is formed over the exposed portion of the conductive feature.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor package component comprising:
a first conductive line and a second conductive line separated from each other by a distance, wherein each of the first conductive line and the second conductive line has a tensile stress;
a first dielectric layer over the first conductive line and the second conductive line, wherein the first dielectric layer has a compressive stress; and
a second dielectric layer between the first conductive line and the first dielectric layer, and between the second conductive line and the first dielectric layer, wherein the second dielectric layer has a tensile stress,
wherein a thickness of the second dielectric layer is in direct proportion to an aspect ratio of a height of the first conductive line to the distance between the first conductive line and the second conductive line.

2. The semiconductor package component of claim 1, wherein the thickness of the second dielectric layer is equal to or less than a thickness of the first dielectric layer.

3. The semiconductor package component of claim 1, wherein:
the thickness of the second dielectric layer is less than 500 angstroms when the aspect ratio is less than 1;
the thickness of the second dielectric layer is between 500 angstroms and 1,000 angstroms when the aspect ratio is between 1 and 2; and
the thickness of the second dielectric layer is greater than 1,000 angstroms when the aspect ratio is greater than 2.

4. The semiconductor package component of claim 1, further comprising a third dielectric layer over the first dielectric layer.

5. The semiconductor package component of claim 4, wherein a portion of the first conductive line is exposed through the first dielectric layer, the second dielectric layer and the third dielectric layer.

6. The semiconductor package component of claim 5, further comprising an external conductor disposed over the portion of the first conductive line exposed through the first dielectric layer, the second dielectric layer and the third dielectric layer.

7. The semiconductor package component of claim 1, wherein the first dielectric layer and the second dielectric layer include a same dielectric material.

8. A semiconductor package component comprising:
a conductive feature having a tensile stress;
a dielectric layer over the conductive feature and having a compressive stress; and
a multi-layered buffer structure between the conductive feature and the dielectric layer, and having a tensile stress;
wherein a thickness of the multi-layered buffer structure is equal to or less than a thickness of the dielectric layer.

9. The semiconductor package component of claim 8, wherein the multi-layered buffer structure comprises:
a first buffer layer having a tensile stress; and
a second buffer layer between the first buffer layer and the dielectric layer.

10. The semiconductor package component of claim 9, wherein the first buffer layer and the second buffer layer comprise different dielectric materials.

11. The semiconductor package component of claim 10, wherein the second buffer layer comprises a compressive stress or is free of stress.

12. The semiconductor package component of claim 10, wherein a thickness of the first buffer layer is greater than a thickness of the second buffer layer.

13. The semiconductor package component of claim 9, wherein the first buffer layer and the second buffer layer comprise a same dielectric material.

14. The semiconductor package component of claim 13, wherein the second buffer layer has a tensile stress, and the tensile stress of the second buffer layer is less than the tensile stress of the first buffer layer.

15. The semiconductor package component of claim 12, wherein a stress of the second buffer layer is approximately 0 MPa.

16. The semiconductor package component of claim 9, wherein the first buffer layer and the dielectric layer comprise a same material.

17. A method for forming a semiconductor package component, comprising:
forming a conductive feature;
forming a tensile-stressed layer over the conductive feature;
forming a compressive-stressed layer over the tensile-stressed layer;
forming a dielectric layer over the compressive-stressed layer;
exposing a portion of a top surface of the conductive feature; and
forming a conductor over the exposed portion of the conductive feature.

18. The method of claim 17, wherein the tensile-stressed layer and the compressive-stressed layer comprise a same material.

19. The method of claim 18, wherein an RF power for forming the tensile-stressed layer is in a range of approximately 400 W to approximately 800 W.

20. The method of claim 18, wherein a RF power for forming the compressive-stressed layer is in a range of approximately 800 W to approximately 1,500 W.
